(19) United States
(12) Patent Application Publication
(10) Pub. No.: US 2010/0067165 A1
(43) Pub. Date: Mar. 18, 2010

(54) Electrostatic chuck and method for manufacturing same

(75) Inventors: Masami Ando, Fukuoka-ken (JP); Takayuki Ide, Fukuoka-ken (JP); Hiromi Arimitsu, Fukuoka-ken (JP)

Correspondence Address: CARRIER BLACKMAN AND ASSOCIATES, 43440 WEST TEN MILE ROAD, EATON CENTER, NOVI, MI, 48375, US

(73) Assignee: Toto Ltd., Kitakyushu-shi (JP)

(21) Appl. No.: 12/584,064

(22) Filed: Aug. 28, 2009

Related U.S. Application Data
(60) Provisional application No. 61/097,866, filed on Sep. 18, 2008.

(30) Foreign Application Priority Data
Aug. 29, 2008 (JP) 2008-221237
Aug. 27, 2009 (JP) 2009-197029

(51) Int. Cl. H01L 21/683; C04B 35/64

(52) U.S. Cl. 361/234; 264/332

(57) ABSTRACT

An electrostatic chuck includes a ceramic member containing yttrium oxide as a main component, containing cerium element and obtained by firing under a nonoxidizing atmosphere. The electrostatic chuck that has high corrosion resistant characteristics and includes a ceramic member having a low volume resistivity with a strong attracting force that utilize the Johnsen-Rahbeck force can be obtained.

### CROSS-REFERENCE TO RELATED APPLICATIONS

This application is based upon and claims the benefit of priorities from the prior Japanese Patent Application No. 2008-221237, filed on Aug. 29, 2008, the prior Japanese Patent Application No. 2009-197029, filed on Aug. 27, 2009 and the prior U.S. Provisional Patent Application No. 61/097,866, filed on Sep. 18, 2008; the entire contents of which are incorporated herein by reference.

### BACKGROUND OF THE INVENTION

1. Field of the Invention

An aspect of the invention relates to an electrostatic chuck and a method for manufacturing the same.

2. Description of the Related Art

An electrostatic chuck is used as a means for attracting and holding a semiconductor substrate or a glass substrate in a plasma processing chamber in which etching, CVD, sputtering, ion implantation, ashing, and the like are performed.

Since corrosive gas such as fluorine-based gas and chlorine-based gas is introduced into the plasma processing chamber to perform a plasma treatment, residues and products derived from a semiconductor wafer or a coating film are attached to the inner face of the chamber after the treatment. The residues and products accumulate gradually as plasma treatments are repeated, and with time, they are separated from the chamber inner face and adhere to the surface of the semiconductor substrate or the glass substrate, causing a decreased yield.

Therefore, so far, the chamber interior is periodically cleaned with plasma to remove residues and products attaching to the chamber inner face. At this time, thus far, the cleaning is performed in a state where the surface of the electrostatic chuck is covered with a dummy wafer in order to prevent the surface of the electrostatic chuck from being exposed to plasma. However, these days, what is called waferless plasma cleaning is widely used in the industry world in order to increase production efficiency, shortening tact time. In this technique, the surface of the electrostatic chuck is not covered with the dummy wafer but is exposed directly to cleaning plasma of O₂ gas, CF₄ gas, and the like during cleaning. Therefore, the material used for members of the chamber interior requires high plasma resistance, and yttria materials have been used in place of alumina.

Also with regard to the electrostatic chuck, a method using yttria is disclosed in Patent Documents 1 and 2. Since the yttria material has volume resistivities of 1×10¹⁵ Ωcm(Ω·cm) or more, the method is related to what is called a Coulomb fource-type electrostatic chuck.

There are two types of electrostatic chuck: one utilizing the Johnsen-Rahbeck force and the other utilizing the Coulomb force. Electrostatic chucks utilizing the Johnsen-Rahbeck force are used for purposes requiring great attracting force. In order to develop an electrostatic attracting force by the Johnsen-Rahbeck force, it is necessary to control the volume resistivity of the dielectric material to not less than 1×10⁸ Ωcm and less than 1×10¹⁴ Ωcm.

A method that adds conductive material to yttria is known as a method for controlling the volume resistivity of yttria. Patent Document 3 describes that the volume resistivity becomes 1×10⁹ Ωcm or less by adding SiC to yttrium oxide at a rate of 2 to 30 wt % and performing sintering by use of a hot press.

Patent Document 4 describes that the volume resistivity becomes 10⁵ to 10¹⁴ Ωcm by adding TiO₂₋ₓ (0<x<2) to yttrium oxide at a rate of 1 to 15 wt %, performing oxidizing atmosphere firing, and then causing the workpiece to be in contact with a material containing carbon as a main component to perform firing under an inert gas or reducing atmosphere or HIP processing.

Patent Document 5 describes that the volume resistivity becomes 10⁻² to 10¹⁰ Ωcm by adding any one of metal yttrium, carbon, yttrium nitride, and yttrium carbide to yttrium oxide at a rate of 0.5 to 10 wt % and performing firing under an inert pressured atmosphere.

Patent Document 6 describes a method for manufacturing a corrosion-resistant member made of yttrium oxide to which a lanthanoid oxide is added at a rate of 5 mass % or less.

On the other hand, the applicant discloses that a dense material can be obtained by adding a boron compound as a sintering-aid agent to yttrium oxide powder to perform firing at 1400 to 1500° C. (for example, refer to Patent Document 7).

### Patent Document 1 JP-A 10-189697 (Kokai)(1998)

### Patent Document 2 JP-A 2007-173596 (Kokai)

### Patent Document 3 JP-A 2006-069843 (Kokai)

### Patent Document 4 JP-A 2001-089229 (Kokai)

### Patent Document 5 JP-A 2005-206402 (Kokai)

### Patent Document 6 JP-A 2005-335991 (Kokai)

### Patent Document 7 JP-A 2007-45700 (Kokai)

### SUMMARY OF THE INVENTION

According to an aspect of the invention, there is provided an electrostatic chuck including a ceramic member containing yttrium oxide as a main component, containing cerium element and obtained by firing under a nonoxidizing atmosphere.

According to a favorable aspect of the invention, there is provided the electrostatic chuck, wherein the cerium element contained in the yttrium oxide in the ceramic member is not less than 5 wt % and not more than 60 wt % on an oxide basis.

According to a favorable aspect of the invention, there is provided the electrostatic chuck, wherein volume resistivity of the ceramic member is not less than 1×10⁷ Ωcm and less than 1×10¹⁴ Ωcm at room temperature.

According to a favorable aspect of the invention, there is provided the electrostatic chuck, wherein a maximum peak position (2θ) obtained by X-ray diffraction at a surface of fired material of the ceramic member according to any one of claims 1 to 3 is shifted to a side of angles lower than a maximum peak position (2θ) obtained by powder X-ray diffraction of powder obtained as reference by crushing a solid solution in which cubic cerium oxide is solid-dissolved in cubic yttrium oxide by oxidizing atmosphere firing. (However, the above reference is powder obtained by crushing a solid solution in which cubic cerium oxide is solid-dissolved in cubic yttrium oxide by oxidizing atmosphere firing.)

According to another aspect of the invention, there is provided a method for manufacturing an electrostatic chuck including: adding cerium oxide to yttrium oxide at a rate of not less than 5 wt % and not more than 60 wt %; molding a mixture thereof; and performing firing under a nonoxidizing atmosphere at not lower than 1300° C. and not higher than 1800° C.

According to another aspect of the invention, there is provided a method for manufacturing an electrostatic chuck including: adding a cerium compound to yttrium oxide at a rate of not less than 5 wt % and not more than 60 wt % on an oxide of cerium basis; molding a mixture thereof, then performs firing under an oxidizing atmosphere at not lower than 1300° C. and not higher than 1800° C.; and performing a heat treatment under a nonoxidizing atmosphere at a temperature of not lower than 1300° C. and not higher than 1800° C.

According to another aspect of the invention, there is provided a method for manufacturing an electrostatic chuck including: adding cerium oxide at a rate of not less than 5 wt % and not more than 60 wt % and a boron compound at a rate of not less than 0.02 wt % and not more than 10 wt % on a boron oxide basis to yttrium oxide; molding a mixture thereof; and performing firing under a nonoxidizing atmosphere at not lower than 1300° C. and not higher than 1600° C.

According to another aspect of the invention, there is provided a method for manufacturing an electrostatic chuck including: adding a cerium compound at a rate of not less than 5 wt % and not more than 60 wt % on an oxide of cerium basis and a boron compound at a rate of not less than 0.02 wt % and not more than 10 wt % on a boron oxide basis to yttrium oxide; molding a mixture thereof; performing firing under an oxidizing atmosphere at not lower than 1300° C. and not higher than 1600° C.; and performing a heat treatment under a nonoxidizing atmosphere at a temperature of not lower than 1300° C. and not higher than 1600° C.

### BRIEF DESCRIPTION OF THE DRAWINGS

FIG. 1 is a view showing an electron microscope photograph of a ceramic member of an electrostatic chuck according to an example of the invention; and

FIG. 2 is a view showing X-ray diffraction profiles at detection angle 2θ=28 to 30° of the ceramic member of the electrostatic chuck according to an example of the invention.

### DETAILED DESCRIPTION OF THE INVENTION

Embodiments of the invention will now be described with reference to the drawings.

Terms used in this case will now be explained.

### (Ceramic Member)

The ceramic member in the invention is a ceramic dielectric substrate used for an electrostatic chuck. Electrodes are formed on one side of the substrate and the substrate is bonded to a metal plate. Thereby, an electrostatic chuck is fabricated.

### (Density)

The density in the invention is apparent density. Specifically, it is the mass of a sample divided by the exterior volume thereof from which open pores are excluded, and was measured by the Archimedes' method.

### (Archimedes' Method)

The Archimedes' method in the invention is a density measuring method provided in JIS standards (JIS R1634). The measurement was performed by using the vacuum method for the water filling method and distilled water for the solvent liquid. The method for calculating pore rate was also carried out according to JIS R1634.

### (Low Resistance)

The volume resistivity of yttrium oxide fired material is 1×10¹⁴ Ωcm or more at room temperature (25° C.). The low resistance in the invention is defined as states of less than 1×10¹⁴ Ωcm in which the volume resistivity of yttrium oxide, which is an insulating material, can be changed intentionally.

### (Volume Resistivity)

The volume resistivity in the invention is the electrical resistance of the test materials provided in JIS standards (JIS C2141) converted to a per-unit-volume basis. Volume resistivities at room temperature (25° C.) were measured by the three-terminal method.

### (Oxidizing Atmosphere)

The oxidizing atmosphere in the invention is an atmosphere containing oxygen, in which air atmosphere and/or oxygen concentration are controlled.

### (Nonoxidizing Atmosphere)

The nonoxidizing atmosphere in the invention is a reducing atmosphere and an inert atmosphere. Specifically, the reducing atmosphere is an atmosphere containing reducing gas such as CO and H₂, and the inert atmosphere is an atmosphere in the case where inert gas such as N₂ and Ar is introduced and heated.

### (X-Ray Diffraction Profile)

The X-ray diffraction profile in the invention is a chart with the angle (2θ) at which a diffracted X-ray is detected on the horizontal axis and the diffraction intensity on the vertical axis, when a sample is irradiated with an X-ray of CuKa line by using a Cu tube. In the invention, an angle (2θ) at which a diffracted X-ray is detected is designated as a peak position, and a peak of which the detected intensity of the diffracted X-ray is highest is designated as a maximum peak.

### (Shift of an X-Ray Diffraction Peak Position to the Low-Angle Side)

The shift of an X-ray diffraction peak position to the low-angle side in the invention is that the 2θ of the X-ray diffraction at the surface of a ceramic member that contains yttrium oxide as a main component and is obtained by firing is shifted to the side of angles lower than the 2θ of the powder X-ray diffraction of the following reference. The reference is powder obtained by crushing a solid solution in which cubic cerium oxide (JCPDF card 01-071-4807) is solid-dissolved in cubic yttrium oxide (JCPDF card 00-041-1105) by oxidizing atmosphere firing.

Next, one embodiment of the invention will now be described.

### (Mixing and Raw Material Powder)

In the case where an oxide is used for a raw material, raw materials are mixed by using a mixing method such as a ball mill used in steps for manufacturing ceramics. Although there is no limit on the particle size of yttrium oxide raw material powder, it is preferably not more than 10 μm and more preferably not more than 2 μm on average. Although there is no limit on the lowest limit, it is preferably not less than 0.1 μm in view of avoiding reduced moldability. Although there is also no limit on the particle size of cerium oxide raw material powder, it is preferably not more than 10 μm and more preferably not more than 2 μm on average. Although there is no limit on the lowest limit, it is preferably not less than 0.1 μm in view of avoiding reduced moldability. Mixing methods such as a ball mill accompanied by a crushing step have effects of not only lowering particle sizes but also crushing coarse particles, and are preferably used in order to obtain a ceramic member made of homogeneous fine particles.

In the case where a water-soluble compound such as cerium nitrate is used as raw material powder that forms an oxide of cerium under an oxidizing atmosphere, then an yttrium oxide raw material is introduced into an aqueous solution of the cerium compound, a wet-mixed slurry is fired under an oxidizing atmosphere, and a loosening step is performed as required. Thereby, (yttrium oxide)-(cerium oxide) raw material powder in which cerium oxide is homogeneously dispersed is obtained, and this can be used as a raw material powder.

### (Molding)

The molding method in the embodiment of the invention can provide a compact by using a dry molding method such as press-molding and CIP on granulated powder. The molding is not limited to dry molding. Molding methods such as extrusion molding, injection molding, sheet molding, casting, and gel-casting may be used to obtain a compact. In the case of dry molding, a binder may be added and a spray dryer etc. may be used to make granules for use.

### (Firing)

In one embodiment of the invention, firing under an oxidizing atmosphere at not lower than 1300° C. and not higher than 1800° C. is possible, and firing in an electrical furnace including an SiC heating element and/or a Kanthal heating element is possible. After the oxidizing atmosphere firing, a heat treatment under a nonoxidizing atmosphere may be performed at temperatures of not lower than 1300° C. and not higher than 1800° C. Thereby, a ceramic member is obtained. The resulting ceramic member may undergo HIP processing as required. Thereby, the open pore rate becomes 0% or more and less than 0.1%, more preferably less than 0.05%, and a dense ceramic member can be obtained.

In one embodiment of the invention, the firing process under the nonoxidizing atmosphere after the firing under the oxidizing atmosphere mentioned above may be replaced with HIP processing, and thereby a ceramic member of the invention can be obtained. Even in the case where the nonoxidizing atmosphere firing is omitted and the HIP processing is performed, a ceramic member equivalent to the fired material mentioned above is obtained. The ceramic member after the HIP processing has an open pore rate of 0% or more and less than 0.1%, more preferably less than 0.05%, and a dense ceramic member can be obtained.

In one embodiment of the invention, firing under a nonoxidizing atmosphere at not lower than 1300° C. and not higher than 1800° C. is possible. A ceramic member of one embodiment of the invention is obtained by the firing under a nonoxidizing atmosphere. The resulting ceramic member may undergo HIP processing as required. Thereby, the open pore rate becomes 0% or more and less than 0.1%, more preferably less than 0.05%, and a dense ceramic member can be obtained.

The following may be used as the cerium compound added to yttrium oxide: a cerium compound that becomes an oxide in the course of firing under an oxidizing atmosphere such as dicerium trioxide (Ce₂O₃), cerium oxide (CeO₂), cerium chloride, ammonium salt of cerium nitrate, hydrate of cerium trinitrate, cerium hydroxide, cerium carbonate, cerium boride, cerium oxalate, and cerium acetate. Cerium oxide may be preferably used.

In the case where a boron compound is added in raw material ceramic in order to improve sinterability, since the boron compound easily evaporates during firing, it is preferable that firing is performed while using a muffle and the like. The boron compound forms Y₃BO₆ in the course of firing and forms a liquid phase at temperatures of 1100 to 1600° C. to promote sintering.

In the case where a boron compound is added, since a liquid phase is formed at temperatures in the range of 1100 to 1600° C., firing is performed preferably at temperatures in the range of not lower than 1300° C. and not higher than 1600° C., and more preferably not lower than 1400° C. and not higher than 1550° C. The firing time may be selected from the range of 0.5 to 8 hours.

Even in the case where a boron compound is added, a desired ceramic member can be obtained by obtaining a fired material by molding, degreasing, and then performing oxidizing atmosphere firing, after which a heat treatment under a nonoxidizing atmosphere of N₂, Ar, CO, H₂ and the like is performed. Further, a desired ceramic member can be obtained by molding and then performing firing under an atmosphere of nitrogen, argon, hydrogen, and the like or firing in a vacuum.

The resulting ceramic sintered material may undergo HIP processing. Thereby, the open pore rate becomes 0% or more and less than 0.1%, more preferably less than 0.05%, and a dense ceramic member can be obtained.

A boron compound that forms the Y₃BO₆ crystal mentioned above is not limited to boron oxide, but may be boric acid, boron nitride, boron carbide, YBO₃, Y₃BO₆ and the like. Among these, boron oxide, boric acid, and YBO₃ may be preferably used.

The specific properties of the fired material obtained by such manufacturing methods will now be described.

In the case where yttrium oxide and cerium oxide are mixed and undergo air firing, it has been confirmed that yttrium oxide and cerium oxide form one crystal phase. This crystal phase has a high volume resistivity of 1×10¹⁵ Ωcm or more at room temperature. However, in the case of the fired material obtained by the nonoxidizing atmosphere firing or the sintered material obtained by the air firing and treated with a nonoxidizing atmosphere, it has been confirmed that the peak position of the crystal phase obtained by the air firing shifts to the low-angle side. It has been found out that the peak-shifted fired material develops a low resistance.

When the lattice constant of the crystal phase obtained by the air firing was calculated from the peak position thereof, it has been confirmed that it is a lattice constant corresponding to the rate of the lattice constants of yttrium oxide and cerium oxide.

On the other hand, the lattice constant of the sample that was fired under the nonoxidizing atmosphere was calculated to be a value larger than the lattice constant obtained by the air firing. It is conceivable that this change of lattice has brought about the peak shift and thus has been confirmed. Since the peak shift is developed by the change of lattice, the phenomenon of peak shift of the proposal is not limited to that of the maximum peak.

### (Electrode Fabrication)

After grinding processing is performed on the surface of the ceramic member mentioned above, a conductive film of TiC, Ti, and the like is formed on one side by CVD and/or PVD, and this conductive film undergoes sandblasting and/or etching. Thereby, a prescribed electrode pattern can be formed.

### (Bonding)

The ceramic member on which the electrodes mentioned above are formed is bonded to a metal plate, on which an insulating film was previously formed by ceramic-spraying, via an insulating adhesive so that the insulating film of the metal plate and the electrodes of the ceramic member may face each other. Ceramics such as alumina and yttria are preferably used for the ceramic-spraying.

### (Surface Pattern Fabrication)

Grinding processing is performed on the ceramic member that is bonded to the metal plate, so that the ceramic member may have a prescribed thickness. Then, convexes having a prescribed size and height are formed on the surface by sandblasting.

The Johnsen-Rahbeck effect can be used by making the volume resistivity of the ceramic member not less than 1×10⁸ Ωcm and less than 1×10¹⁴ Ωcm at room temperature. This can develop a very great attracting force, and thus can fabricate an electrostatic chuck that allows itself to have convexes on the surface.

The corrosion-resistant member according to one embodiment of the invention is a ceramic member made of yttrium oxide and cerium element. Since the added cerium element does not exist separately at the grain boundaries or the triple junctions of yttrium oxide, a ceramic member having a high plasma resistance is obtained without impairing the corrosion-resistant characteristics of yttrium oxide.

### Example 1

Yttrium oxide powder (Y₂O₃, average particle size: 1 μm, specific surface area: 11 to 15 g/cm²) and cerium oxide powder (CeO₂, average particle size: 0.6 μm, specific surface area: approximately 20 g/cm²) were prepared as raw materials.

Yttrium oxide powder, cerium oxide powder and boron oxide powder (as a reagent) were mixed so that the additive amount of cerium oxide was 5 wt %, boron oxide was 1 wt % (viz. yttrium oxide: 94 wt %). Furthermore, a dispersing agent, a binder, and a mold releasing agent were added into the mixture (yttrium oxide, cerium oxide and boron oxide) to perform crushing stirring mixing by use of a ball mill.

After mixing, granulation with a spray dryer was performed. The resulting granulated powder underwent press molding and then CIP molding. A fired material is obtained stably by performing the granulation with the spray dryer and the CIP processing to increase the compact density. The resulting compact was degreased, and then was fired under an oxidizing atmosphere at 1480° C. The resulting fired material underwent HIP processing under an argon atmosphere of 100 MPa at 1500° C. for two hours.

### Example 2

Yttrium oxide powder (Y₂O₃, average particle size: 1 μm, specific surface area: 11 to 15 g/cm²) and cerium oxide powder (CeO₂, average particle size: 0.6 μm, specific surface area: approximately 20 g/cm²) were prepared as raw materials.

Yttrium oxide powder, cerium oxide powder and boron oxide powder (reagent) were mixed so that the additive amount of cerium oxide was 10 wt %, boron oxide was 1 wt % (viz. yttrium oxide: 89 wt %). Furthermore, a dispersing agent, a binder, and a mold releasing agent were added into the mixture (yttrium oxide, cerium oxide and boron oxide) to perform crushing stirring mixing by use of a ball mill.

After mixing, granulation with a spray dryer was performed. The resulting granulated powder underwent press molding and then CIP molding. A fired material is obtained stably by performing the granulation with the spray dryer and the CIP processing to increase the compact density. The resulting compact was degreased, and then was fired under an oxidizing atmosphere at 1480° C. The resulting fired material underwent HIP processing under an argon atmosphere of 100 MPa at 1500° C. for two hours.

### Example 3

Yttrium oxide powder (Y₂O₃, average particle size: 1 μm, specific surface area: 11 to 15 g/cm²) and cerium oxide powder (CeO₂, average particle size: 0.6 μm, specific surface area: approximately 20 g/cm²) were prepared as raw materials.

Yttrium oxide powder and cerium oxide powder were mixed so that the additive amount of cerium oxide was 20 wt % (viz. yttrium oxide: 80 wt %). Furthermore, a dispersing agent, a binder, and a mold releasing agent were added into the mixture (yttrium oxide and cerium oxide) to perform crushing stirring mixing by use of a ball mill.

After mixing, granulation with a spray dryer was performed. The resulting granulated powder underwent press molding and then CIP molding. A fired material is obtained stably by performing the granulation with the spray dryer and the CIP processing to increase the compact density. The resulting compact was degreased, and then was fired under an oxidizing atmosphere at 1650° C. The resulting fired material underwent HIP processing under an argon atmosphere of 100 MPa at 1500° C. for two hours.

### Example 4

Yttrium oxide powder (Y₂O₃, average particle size: 1 μm, specific surface area: 11 to 15 g/cm²) and cerium oxide powder (CeO₂, average particle size: 0.6 μm, specific surface area: approximately 20 g/cm²) were prepared as raw materials.

Yttrium oxide powder and cerium oxide powder were mixed so that the additive amount of cerium oxide was 40 wt % (viz. yttrium oxide: 60 wt %). Furthermore, a dispersing agent, a binder, and a mold releasing agent were added into the mixture (yttrium oxide and cerium oxide) to perform crushing stirring mixing by use of a ball mill.

After mixing, granulation with a spray dryer was performed. The resulting granulated powder underwent press molding and then CIP molding. A fired material is obtained stably by performing the granulation with the spray dryer and the CIP processing to increase the compact density. The resulting compact was degreased, and then was fired under an oxidizing atmosphere at 1650° C. The resulting fired material underwent HIP processing under an argon atmosphere of 100 MPa at 1500° C. for two hours.

### Example 5

Yttrium oxide powder (Y₂O₃, average particle size: 1 μm, specific surface area: 11 to 15 g/cm²) and cerium oxide powder (CeO₂, average particle size: 0.6 μm, specific surface area: approximately 20 g/cm²) were prepared as raw materials.

Yttrium oxide powder and cerium oxide powder were mixed so that the additive amount of cerium oxide was 60 wt % (viz. yttrium oxide: 40 wt %). Furthermore, a dispersing agent, a binder, and a mold releasing agent were added into the mixture (yttrium oxide and cerium oxide) to perform crushing stirring mixing by use of a ball mill.

After mixing, granulation with a spray dryer was performed. The resulting granulated powder underwent press molding and then CIP molding. A fired material is obtained stably by performing the granulation with the spray dryer and the CIP processing to increase the compact density. The resulting compact was degreased, and then was fired under an oxidizing atmosphere at 1650° C. The resulting fired material underwent HIP processing under an argon atmosphere of 100 MPa at 1500° C. for two hours.

### Example 6

Yttrium oxide powder (Y₂O₃, average particle size: 1 μm, specific surface area: 11 to 15 g/cm²) and cerium oxide powder (CeO₂, average particle size: 0.6 μm, specific surface area: approximately 20 g/cm²) were prepared as raw materials.

Yttrium oxide powder and cerium oxide powder were mixed so that the additive amount of cerium oxide was 5 wt % (viz. yttrium oxide: 95 wt %). Furthermore, a dispersing agent, a binder, and a mold releasing agent were added into the mixture (yttrium oxide and cerium oxide) to perform crushing stirring mixing by use of a ball mill.

After mixing, granulation with a spray dryer was performed. The resulting granulated powder underwent press molding and then CIP molding. A fired material is obtained stably by performing the granulation with the spray dryer and the CIP processing to increase the compact density. The resulting compact was degreased, and then was fired under an oxidizing atmosphere at 1650° C. The resulting fired material underwent HIP processing under an argon atmosphere of 100 MPa at 1500° C. for two hours.

### Example 7

Yttrium oxide powder (Y₂O₃, average particle size: 1 μm, specific surface area: 11 to 15 g/cm²) and cerium oxide powder (CeO₂, average particle size: 0.6 μm, specific surface area: approximately 20 g/cm²) were prepared as raw materials.

Yttrium oxide powder and cerium oxide powder were mixed so that the additive amount of cerium oxide was 15 wt % (viz. yttrium oxide: 85 wt %). Furthermore, a dispersing agent, a binder, and a mold releasing agent were added into the mixture (yttrium oxide and cerium oxide) to perform crushing stirring mixing by use of a ball mill.

After mixing, granulation with a spray dryer was performed. The resulting granulated powder underwent press molding and then CIP molding. A fired material is obtained stably by performing the granulation with the spray dryer and the CIP processing to increase the compact density. The resulting compact was degreased, and then was fired under an oxidizing atmosphere at 1650° C. The resulting fired material underwent HIP processing under an argon atmosphere of 100 MPa at 1500° C. for two hours.

### Example 8

Yttrium oxide powder (Y₂O₃, average particle size: 1 μm, specific surface area: 11 to 15 g/cm²) and cerium oxide powder (CeO₂, average particle size: 0.6 μm, specific surface area: approximately 20 g/cm²) were prepared as raw materials.

Yttrium oxide powder, cerium oxide powder and boron oxide powder (reagent) were mixed so that the additive amount of cerium oxide was 20 wt %, boron oxide was 1 wt % (viz. yttrium oxide: 79 wt %). Furthermore, a dispersing agent, a binder, and a mold releasing agent were added into the mixture (yttrium oxide, cerium oxide and boron oxide) to perform crushing stirring mixing by use of a ball mill.

After mixing, granulation with a spray dryer was performed. The resulting granulated powder underwent press molding and then CIP molding. A fired material is obtained stably by performing the granulation with the spray dryer and the CIP processing to increase the compact density. The resulting compact was degreased, and then was fired under an oxidizing atmosphere at 1480° C. The resulting fired material underwent HIP processing under an argon atmosphere of 100 MPa at 1500° C. for two hours.

### Comparative Example 1

Yttrium oxide powder (Y₂O₃, average particle size: 1 μm, specific surface area: 11 to 15 g/cm²) and cerium oxide powder (CeO₂, average particle size: 0.6 μm, specific surface area: approximately 20 g/cm²) were prepared as raw materials.

Yttrium oxide powder and cerium oxide powder were mixed so that the additive amount of cerium oxide was 80 wt % (viz. yttrium oxide: 20 wt %). Furthermore, a dispersing agent, a binder, and a mold releasing agent were added into the mixture (yttrium oxide and cerium oxide) to perform crushing stirring mixing by use of a ball mill.

After mixing, granulation with a spray dryer was performed. The resulting granulated powder underwent press molding and then CIP molding. The resulting compact was degreased, and then was fired under an oxidizing atmosphere at 1650° C. The sample to which cerium oxide was added at a rate of 80 wt % had a cracking due to the heat treatment for degreasing, and was difficult to calcine. Thus, the volume resistivity of the resulting fired material was not measured.

### Comparative Example 2

Comparative Example 2 is a high-purity yttrium oxide fired material.

### Comparative Example 3

Comparative Example 3 is a high-purity aluminum oxide fired material with a purity of 99.7%.

### Comparative Example 4

Yttrium oxide powder (Y₂O₃, average particle size: 1 μm, specific surface area: 11 to 15 g/cm²) and cerium oxide powder (CeO₂, average particle size: 0.6 μm, specific surface area: approximately 20 g/cm²) were prepared as raw materials.

Yttrium oxide powder and cerium oxide powder were mixed so that the additive amount of cerium oxide was 20 wt %. Furthermore, a dispersing agent, a binder, and a mold releasing agent were added into the mixture (yttrium oxide and cerium oxide) to perform crushing stirring mixing by use of a ball mill.

After mixing, granulation with a spray dryer was performed. The resulting granulated powder underwent press molding and then CIP molding. A fired material is obtained stably by performing the granulation with the spray dryer and the CIP processing to increase the compact density. The resulting compact was degreased, and then was fired under an oxidizing atmosphere at 1650° C.

### Comparative Example 5

Yttrium oxide powder (Y₂O₃, average particle size: 1 μm, specific surface area: 11 to 15 g/cm²) and cerium oxide powder (CeO₂, average particle size: 0.6 μm, specific surface area: approximately 20 g/cm²) were prepared as raw materials.

Yttrium oxide powder and cerium oxide powder were mixed so that the additive amount of cerium oxide was 40 wt %. Furthermore, a dispersing agent, a binder, and a mold releasing agent were added into the mixture (yttrium oxide and cerium oxide) to perform crushing stirring mixing by use of a ball mill.

After mixing, granulation with a spray dryer was performed. The resulting granulated powder underwent press molding and then CIP molding. A fired material is obtained stably by performing the granulation with the spray dryer and the CIP processing to increase the compact density. The resulting compact was degreased, and then was fired under an oxidizing atmosphere at 1650° C.

### Comparative Example 6

Yttrium oxide powder (Y₂O₃, average particle size: 1 μm, specific surface area: 11 to 15 g/cm²) and cerium oxide powder (CeO₂, average particle size: 0.6 μm, specific surface area: approximately 20 g/cm²) were prepared as raw materials.

Yttrium oxide powder and cerium oxide powder were mixed so that the additive amount of cerium oxide was 60 wt %. Furthermore, a dispersing agent, a binder, and a mold releasing agent were added into the mixture (yttrium oxide and cerium oxide) to perform crushing stirring mixing by use of a ball mill.

After mixing, granulation with a spray dryer was performed. The resulting granulated powder underwent press molding and then CIP molding. A fired material is obtained stably by performing the granulation with the spray dryer and the CIP processing to increase the compact density. The resulting compact was degreased, and then was fired under an oxidizing atmosphere at 1650° C.

### Comparative Example 7

Yttrium oxide powder (Y₂O₃, average particle size: 1 μm, specific surface area: 11 to 15 g/cm²) and cerium oxide powder (CeO₂, average particle size: 0.6 μm, specific surface area: approximately 20 g/cm²) were prepared as raw materials.

Yttrium oxide powder and cerium oxide powder were mixed so that the additive amount of cerium oxide was 5 wt %. Furthermore, a dispersing agent, a binder, and a mold releasing agent were added into the mixture (yttrium oxide and cerium oxide) to perform crushing stirring mixing by use of a ball mill.

After mixing, granulation with a spray dryer was performed. The resulting granulated powder underwent press molding and then CIP molding. A fired material is obtained stably by performing the granulation with the spray dryer and the CIP processing to increase the compact density. The resulting compact was degreased, and then was fired under an oxidizing atmosphere at 1650° C.

### Comparative Example 8

Yttrium oxide powder (Y₂O₃, average particle size: 1 μm, specific surface area: 11 to 15 g/cm²) and cerium oxide powder (CeO₂, average particle size: 0.6 μm, specific surface area: approximately 20 g/cm²) were prepared as raw materials.

Yttrium oxide powder and cerium oxide powder were mixed so that the additive amount of cerium oxide was 15 wt %. Furthermore, a dispersing agent, a binder, and a mold releasing agent were added into the mixture (yttrium oxide and cerium oxide) to perform crushing stirring mixing by use of a ball mill.

After mixing, granulation with a spray dryer was performed. The resulting granulated powder underwent press molding and then CIP molding. A fired material is obtained stably by performing the granulation with the spray dryer and the CIP processing to increase the compact density. The resulting compact was degreased, and then was fired under an oxidizing atmosphere at 1650° C.

The densities and the volume resistivities of the ceramic members obtained by Examples 1 to 8 and Comparative Example 1 are shown in Table 1. The volume resistivities of the ceramic members of Examples 1 to 8 were not less than 1×10⁷ Ωcm and less than 1×10¹⁴ Ωcm, and ceramic members suitable for utilizing the Johnson-Rahbeck force were obtained.

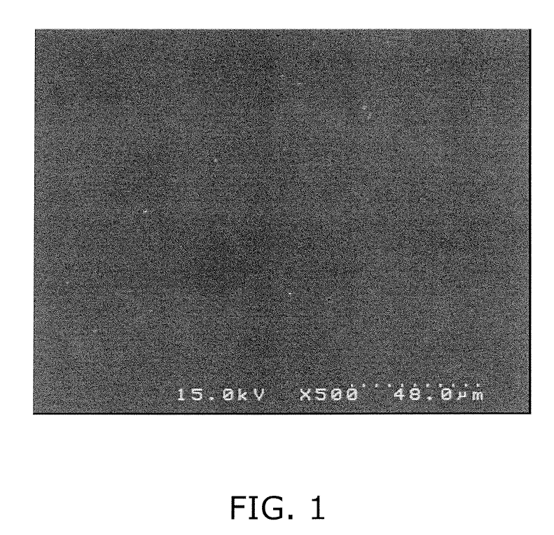

Further, the ceramic members of Examples 1 to 8 were dense. The electron microscope photograph of the cross-section of the ceramic member of Example 4 is shown in FIG. 1 as a representative example. This ceramic member is composed of homogeneous structures, which are dense structures that do not include pores, and a ceramic member that experiences insulation breakdown with difficulty was obtained.

From the above results, ceramic members that have a volume resistivity of not less than 1×10⁷ Ωcm and less than 1×10¹⁴ Ωcm at room temperature were fabricated, and electrostatic chucks with a strong attracting force that utilize the Johnsen-Rahbeck force were obtained, by adding the cerium element into the yttrium oxide at a rate of not less than 5 wt % and not more than 60 wt % on an oxide basis.

TABLE 1

| | | | | Fired | |
|---|---|---|---|---|---|
| | | | | material | Volume |
| | Composition (wt %) | | | density | resistivity |
| | Y₂O₃ | CeO₂ | B₂O₃ | (g/cm³) | (Ω cm) |
| Example 1 | 94 | 5 | 1 | 5.06 | 3.1 × 10¹³ |
| Example 2 | 89 | 10 | 1 | 5.11 | 3.0 × 10¹¹ |
| Example 3 | 80 | 20 | 0 | 5.25 | 5.1 × 10⁹ |
| Example 4 | 60 | 40 | 0 | 5.46 | 1.6 × 10⁷ |
| Example 5 | 40 | 60 | 0 | 5.77 | 1.5 × 10⁷ |
| Example 6 | 95 | 5 | 0 | 5.08 | 9.4 × 10¹¹ |
| Example 7 | 85 | 15 | 0 | 5.19 | 7.5 × 10¹⁰ |
| Example 8 | 79 | 20 | 1 | 5.21 | 7.7 × 10⁹ |
| Comparative | 20 | 80 | 0 | Firing | |
| Example 1 | | | | impossible | |

In order to evaluate the plasma resistance of the corrosion-resistant members of the one embodiment of the invention, a plasma irradiation treatment of 1000 W for thirty hours was performed on the ceramic members of Examples 1 to 8 and Comparative Examples 2 and 3, by using an reactive ion etching apparatus (ANELVA Corporation, DEA-506) and etching gases of CF₄ (40 sccm) and O₂ (10 sccm). The results are shown in Table 2.

TABLE 2

| | Composition (wt %) | | | Etching rate |
|---|---|---|---|---|
| | Y₂O₃ | CeO₂ | B₂O₃ | (nm/h) |
| Example 1 | 94 | 5 | 1 | 78 to 80 |
| Example 2 | 89 | 10 | 1 | 54 to 62 |
| Example 3 | 80 | 20 | 0 | 40 to 55 |
| Example 4 | 60 | 40 | 0 | 57 to 76 |
| Example 5 | 40 | 60 | 0 | 65 to 78 |
| Example 6 | 95 | 5 | 0 | 44 to 52 |
| Example 7 | 85 | 15 | 0 | 51 to 58 |
| Example 8 | 79 | 20 | 1 | 43 to 60 |
| Comparative | 100 | 0 | 0 | 40 to 80 |
| Example 2 | | | | |

| | | |
|---|---|---|
| Comparative | Al₂O₃ | 220 to 300 |
| Example 3 | | |

It becomes clear that the ceramic members of Examples 1 to 8 have a plasma resistance equal to or more than that of the high-purity yttrium oxide of Comparative Example 2 and have a quite excellent plasma resistance compared to the high-purity alumina of Comparative Example 3.

The relationships between the amount of added cerium oxide, the firing atmosphere, and the maximum peak position (2θ/CuKa) of Examples 3 to 7 and Comparative Examples 4 to 8 are shown in Table 3.

The peak shift after the nonoxidizing atmosphere firing varies with the amount of added cerium oxide, and the shift amount tends to increase as the amount of added cerium oxide increases. Further, it has been confirmed that the resistance value tends to decrease as the shift amount increases.

TABLE 3

| | | | 2θ/degree | Resistance |
|---|---|---|---|---|
| | | | (CuKα) | value (Ωcm) |
| Example 3 | CeO₂ | Reducing | 28.91 | 5.1 × 10⁹ |
| | 20 wt % | atmosphere | | |
| | | firing | | |
| Example 4 | CeO₂ | Reducing | 28.70 | 1.6 × 10⁷ |
| | 40 wt % | atmosphere | | |
| | | firing | | |
| Example 5 | CeO₂ | Reducing | 28.43 | 1.5 × 10⁷ |
| | 60 wt % | atmosphere | | |
| | | firing | | |
| Example 6 | CeO₂ | Reducing | 29.07 | 9.4 × 10¹¹ |
| | 5 wt % | atmosphere | | |
| | | firing | | |
| Example 7 | CeO₂ | Reducing | 28.93 | 7.5 × 10¹⁰ |
| | 15 wt % | atmosphere | | |
| | | firing | | |
| Comparative | CeO₂ | Oxidizing | 29.02 | 1 × 10¹⁵ or more |
| Example 4 | 20 wt % | atmosphere | | |
| | | firing | | |
| Comparative | CeO₂ | Oxidizing | 28.98 | 1 × 10¹⁵ or more |
| Example 5 | 40 wt % | atmosphere | | |
| | | firing | | |
| Comparative | CeO₂ | Oxidizing | 28.94 | 1 × 10¹⁵ or more |
| Example 6 | 60 wt % | atmosphere | | |
| | | firing | | |
| Comparative | CeO₂ | Oxidizing | 29.08 | 1 × 10¹⁵ or more |
| Example 7 | 5 wt % | atmosphere | | |
| | | firing | | |
| Comparative | CeO₂ | Oxidizing | 29.98 | 1 × 10¹⁵ or more |
| Example 8 | 15 wt % | atmosphere | | |
| | | firing | | |

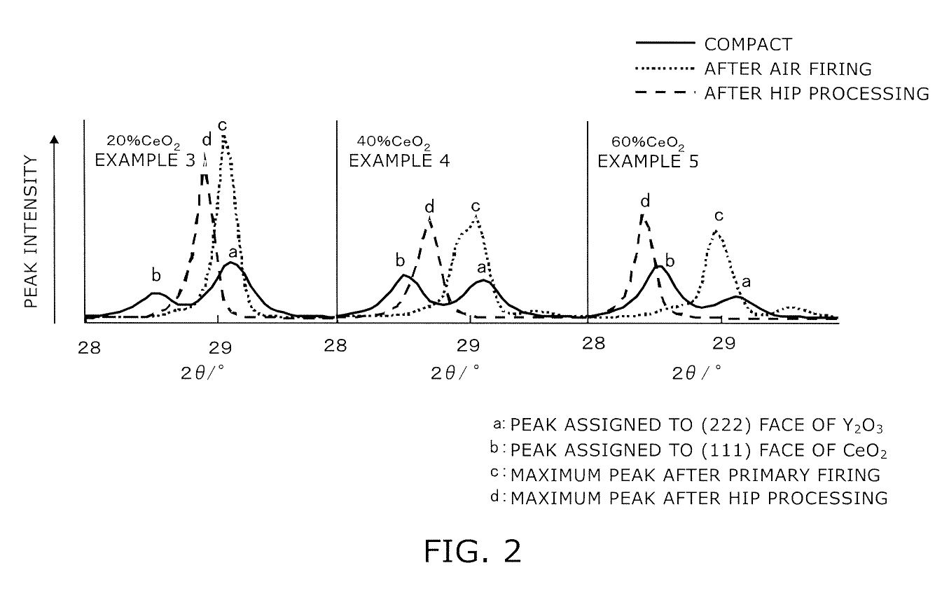

With respect to the ceramic members of Examples 3 to 5, the changes in the maximum peak position in the X-ray diffraction profiles of the compact, the air-fired material, and the HIP-processed material are shown in FIG. 2.

With regard to the compacts, the peak (“a” in the figure) assigned to (222) of yttrium oxide and the peak (“b” in the figure) assigned to (111) of cerium oxide are separated. The two peaks become one (“c” in the figure) by the air firing, and the peak position is located between the two peaks. After the HIP, a shift from the position of c to the low-angle side was observed (“d” in the figure). This phenomenon, that is, the behavior of the shift to the low-angle side by the HIP processing, was observed regardless of the amount of added cerium.

1. An electrostatic chuck comprising a ceramic member containing yttrium oxide as a main component, containing cerium element and obtained by firing under a nonoxidizing atmosphere.

2. The electrostatic chuck according to claim 1, wherein the cerium element contained in the yttrium oxide in the ceramic member is not less than 5 wt % and not more than 60 wt % on an oxide basis.

3. The electrostatic chuck according to claim 1, wherein volume resitivity of the ceramic member is not less than 1×10⁷ Ωcm and less than 1×10¹⁴ Ωcm at room temperature.

4. The electrostatic chuck, wherein a maximum peak position (2θ) obtained by X-ray diffraction at a surface of fired material of the ceramic member according to claim 1 is shifted to a side of angles lower than a maximum peak position (2θ) obtained by powder X-ray diffraction of powder obtained as reference by crushing a solid solution in which cubic cerium oxide is solid-dissolved in cubic yttrium oxide by oxidizing atmosphere firing.

5. A method for manufacturing an electrostatic chuck comprising: adding cerium oxide to yttrium oxide at a rate of not less than 5 wt % and not more than 60 wt %; molding a mixture thereof; and performing firing under a nonoxidizing atmosphere at not lower than 1300° C. and not higher than 1800° C.

6. A method for manufacturing an electrostatic chuck comprising: adding a cerium compound to yttrium oxide at a rate of not less than 5 wt % and not more than 60 wt % on an oxide of cerium basis; molding a mixture thereof; performing firing under an oxidizing atmosphere at not lower than 1300° C. and not higher than 1800° C.; and performing a heat treatment under a nonoxidizing atmosphere at a temperature of not lower than 1300° C. and not higher than 1800° C.

7. A method for manufacturing an electrostatic chuck comprising: adding cerium oxide at a rate of not less than 5 wt % and not more than 60 wt % and a boron compound at a rate of not less than 0.02 wt % and not more than 10 wt % on a boron oxide basis to yttrium oxide; molding a mixture thereof; and performing firing under a nonoxidizing atmosphere at not lower than 1300° C. and not higher than 1600° C.

8. A method for manufacturing an electrostatic chuck comprising: adding a cerium compound at a rate of not less than 5 wt % and not more than 60 wt % on an oxide of cerium basis and a boron compound at a rate of not less than 0.02 wt % and not more than 10 wt % on a boron oxide basis to yttrium oxide; molding a mixture thereof; performing firing under an oxidizing atmosphere at not lower than 1300° C. and not higher than 1600° C.; and performing a heat treatment under a nonoxidizing atmosphere at a temperature of not lower than 1300° C. and not higher than 1600° C.

9. The electrostatic chuck, wherein a maximum peak position (2θ) obtained by X-ray diffraction at a surface of fired material of the ceramic member according to claim 2 is shifted to a side of angles lower than a maximum peak position (2θ) obtained by powder X-ray diffraction of powder obtained as reference by crushing a solid solution in which cubic cerium oxide is solid-dissolved in cubic yttrium oxide by oxidizing atmosphere firing.

10. The electrostatic chuck, wherein a maximum peak position (2θ) obtained by X-ray diffraction at a surface of fired material of the ceramic member according to claim 3 is shifted to a side of angles lower than a maximum peak position (2θ) obtained by powder X-ray diffraction of powder obtained as reference by crushing a solid solution in which cubic cerium oxide is solid-dissolved in cubic yttrium oxide by oxidizing atmosphere firing.
